(19) United States
(12) Patent Application Publication
(10) Pub. No.: US 2025/0264817 A1
(43) Pub. Date: Aug. 21, 2025

(54) MEASURING METHOD, MEASURING APPARATUS, LITHOGRAPHY APPARATUS, AND ARTICLE MANUFACTURING METHOD

(71) Applicant: CANON KABUSHIKI KAISHA, Tokyo (JP)

(72) Inventors: KAZUKI OTA, Tochigi (JP); WATARU YAMAGUCHI, Tochigi (JP); SHINICHIRO HIRAI, Saitama (JP)

(21) Appl. No.: 19/056,497

(22) Filed: Feb. 18, 2025

(30) Foreign Application Priority Data
Feb. 21, 2024 (JP) 2024-024827

(51) Int. Cl. G03F 9/00; G01N 21/21; G01N 21/31

(52) U.S. Cl. CPC G03F 9/7076; G01N 21/21; G01N 21/31; G03F 9/7003; G03F 9/7069; G03F 9/7092

(57) ABSTRACT

A measuring method includes performing preliminary measurement for obtaining signal information obtained by detecting, using measurement light, a plurality of targets formed on a substrate a plurality of times while changing a parameter value of a measurement parameter, acquiring a relationship between the parameter value and the signal information based on results of the preliminary measurement performed the plurality of times, determining a target for which main measurement should be performed, in the plurality of targets, based on the acquired relationship, and performing the main measurement for the determined target.

### BACKGROUND

### Technical Field

The present disclosure relates to a measuring method, a measuring apparatus, a lithography apparatus, and an article manufacturing method.

### Description of the Related Art

In a lithography apparatus such as an exposure apparatus used in a lithography process, importance is placed on the alignment accuracy between a shot region on a substrate and an original and the overlay accuracy between different layers on the substrate. As a method for improving the alignment or overlay accuracy, there is a method of selecting a measurement mark or measurement processing condition which is less susceptible to degradation of measurement accuracy caused by a change in substrate characteristic. With this method, it is possible to maximize the intensity and quality of a measurement signal from the measurement mark, and implement measurement with high accuracy.

In Japanese Patent Laid-Open No. 2023-184422, a method is described, which determines the parameter value of a measurement parameter for the purpose of improving the measurement accuracy of a mark formed on a substrate. A sensitivity indicating a change of a measurement value with respect to a change of the parameter value is acquired, and a parameter value that should be employed is determined based on a sensitivity distribution.

However, if the shape or characteristic of the mark formed on the substrate changes, the intensity and quality of a measurement signal from the mark lower, and this may cause lowering of the measurement accuracy.

### SUMMARY

The present disclosure provides a technique advantageous in implementing a high measurement accuracy.

The present disclosure in its one aspect provides a measuring method including performing preliminary measurement for obtaining signal information obtained by detecting, using measurement light, a plurality of targets formed on a substrate a plurality of times while changing a parameter value of a measurement parameter, acquiring a relationship between the parameter value and the signal information based on results of the preliminary measurement performed the plurality of times, determining a target for which main measurement should be performed, in the plurality of targets, based on the acquired relationship, and performing the main measurement for the determined target.

Further features of the present disclosure will become apparent from the following description of exemplary embodiments (with reference to the attached drawings).

### BRIEF DESCRIPTION OF THE DRAWINGS

FIGS. 1A and 1B are views showing the configuration of a measuring apparatus;

FIGS. 2A and 2B are views showing examples of sample regions of a substrate;

FIGS. 3A and 3B are views showing an example of the configuration of a measurement pattern and an example of derivation of a measurement value;

FIGS. 4A and 4B are views for explaining a central wavelength and a bandwidth of the wavelength as measurement parameters;

FIG. 5 is a flowchart showing the sequence of measurement processing;

FIGS. 6A to 6D are views for explaining measurement processing;

FIGS. 7A to 7C are views for explaining a method of determining measurement processing conditions based on the relationship between the measurement parameters and signal information;

FIG. 8 is a view for explaining a method of determining a processing region that is a measurement processing condition;

FIG. 9 is a view for explaining estimation of an overlay measurement value;

FIG. 10 is a flowchart showing the sequence of measurement processing;

FIG. 11 is a flowchart showing the sequence of measurement processing;

FIG. 12 is a view for explaining a method of determining a processing region that is a measurement processing condition;

FIG. 13 is a flowchart showing the sequence of measurement processing;

FIG. 14 is a view showing the configuration of an exposure apparatus; and

FIG. 15 is a flowchart showing the sequence of exposure processing.

### DESCRIPTION OF THE EMBODIMENTS

Hereinafter, embodiments will be described in detail with reference to the attached drawings. Note, the following embodiments are not intended to limit the scope of the claims. Multiple features are described in the embodiments, but limitation is not made to an embodiment that requires all such features, and multiple such features may be combined as appropriate. Furthermore, in the attached drawings, the same reference numerals are given to the same or similar configurations, and redundant description thereof is omitted.

### First Embodiment

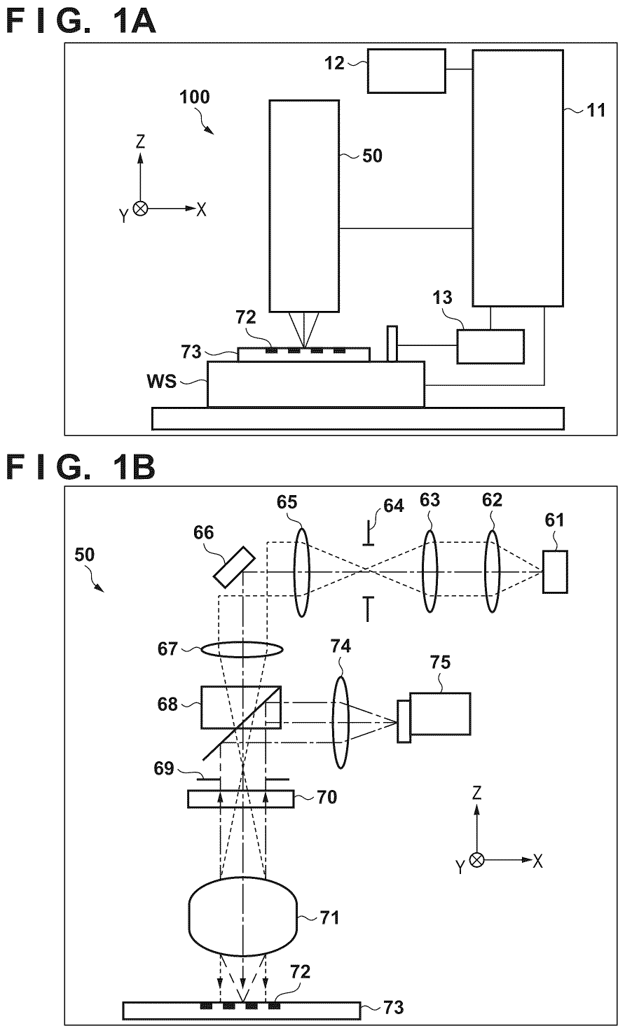

FIG. 1A is a view showing the configuration of a measuring apparatus 100 according to the embodiment. In the specification and the accompanying drawings, directions will be indicated on an XYZ coordinate system in which a horizontal surface is defined as the X-Y plane. Generally, a substrate 73 is placed on a substrate stage WS so that the surface of the substrate 73 becomes parallel to the horizontal surface (X-Y plane). In the following description, directions orthogonal to each other within a plane along the upper surface of the substrate stage WS on which the substrate 73 is placed will be defined as the X-axis and the Y-axis, and a direction perpendicular to the X-axis and the Y-axis will be defined as the Z-axis. Also, in the following description, directions parallel to the X-axis, the Y-axis, and the Z-axis in the XYZ coordinate system will be referred to as the X direction, the Y direction, and the Z direction, respectively.

The measuring apparatus 100 can be configured as a detection apparatus that measures or detects the position of a target formed on the substrate 73. Alternatively, the measuring apparatus 100 can be configured as an overlay inspection apparatus that measures the relative position between a plurality of targets provided in different layers of the substrate 73. The target can be a mark or a pattern formed on the substrate 73. The pattern may be a pattern formed only for the purpose of being used as a mark or may be a predetermined device pattern. A measurement target object that is used as a target will uniformly be referred to as “pattern” hereinafter. The measuring apparatus 100 includes the substrate stage WS that holds the substrate 73, an image capturing unit 50 (measuring unit), a controller 11, and an interface 12.

The substrate 73 can be used to, for example, manufacture a device such as a semiconductor device or a liquid crystal display device. The substrate 73 can be, for example, a wafer or glass substrate. The substrate stage WS holds the substrate 73 via a substrate chuck (not shown) and can be driven or positioned by a substrate driving mechanism (not shown). The substrate driving mechanism includes a linear motor or the like and can move the substrate 73 held by the substrate stage WS by driving the substrate stage WS in the X direction, the Y direction, the Z direction, and the rotation directions about the respective axes. The position of the substrate stage WS is monitored by, for example, a 6-axis laser interferometer 13, and the substrate stage WS is driven to a predetermined position under the control of the controller 11.

The controller 11 is formed by a computer (information processing apparatus) including a CPU, a memory, and the like and, for example, comprehensively controls the constituent elements of the measuring apparatus 100 in accordance with a program stored in a storage unit. Based on a measurement result obtained by the image capturing unit 50, more specifically, an image obtained by capturing a measurement pattern formed on the substrate 73, the controller 11 can perform various kinds of correction processing (arithmetic processing). The interface 12 can include a display device and an input device. A user can designate, via the interface 12, the position of a shot region as a measurement target in a plurality of shot regions formed on the substrate 73, or a measurement pattern in the shot region.

The configuration of the image capturing unit 50 will be described with reference to FIG. 1B. The image capturing unit 50 can include an illumination system that illuminates the substrate 73 using light from a light source 61, and an imaging system (detection system) that forms, on an image capturing element 75, an image of a measurement pattern 72 formed on the substrate 73. The light from the light source 61 is guided to an illumination aperture stop 64 via lenses 62 and 63. The light source 61 can be, for example, a laser source, an LED, or a halogen lamp but is not limited to these. The light that has passed through the illumination aperture stop 64 is guided to a polarization beam splitter 68 via a lens 65, a mirror 66, and a lens 67. P-polarized light transmitted through the beam splitting surface of the polarization beam splitter 68 passes through an aperture stop 69 and is then converted into circularly polarized light via a λ/4 plate 70, and Koehler-illuminates the measurement pattern 72 formed on the substrate 73 via an objective lens 71.

The light reflected, diffracted, and scattered by the Koehler-illuminated measurement pattern 72 passes through the objective lens 71 and the λ/4 plate 70 and is guided to the aperture stop 69. Here, the polarization state of the light from the measurement pattern 72 is circular polarization that is reverse to the circular polarization of the light Koehler-illuminating the measurement pattern 72. When passing through the λ/4 plate 70, the light is converted from circularly polarized light to S-polarized light. The S-polarized light passes through the aperture stop 69 and is then reflected by the beam splitting surface of the polarization beam splitter 68 and guided to the image capturing element 75 via a lens 74.

Note that the illumination optical system may be provided with a light amount adjustment unit (not shown) or a wavelength adjustment unit (not shown). The light amount adjustment unit can include, for example, a plurality of ND filters having different transmittances to the light from the light source 61. The plurality of ND filters are arranged in a switchable state. The light amount adjustment unit can adjust the intensity of light to illuminate the substrate 73 by controlling switching of the ND filters.

The wavelength adjustment unit can include, for example, a wavelength variable element and a driving mechanism that drives the wavelength variable element. The driving mechanism includes a linear motor or the like and drives the wavelength variable element along a predetermined direction (for example, the X direction), thereby adjusting the wavelength (for example, the central wavelength and the bandwidth of the wavelength) of light (measurement light) that illuminates the measurement pattern 72.

Note that as a method of changing the wavelength of the light from the measurement pattern 72, there is a method using a color sensor or a multi-spectrum sensor, in which a different wavelength filter is arranged for each pixel, in addition to the above-described method using a wavelength filter or a wavelength variable element. Alternatively, a method using a hyper spectrum sensor including a diffractive optical element or a multi-camera including a wavelength division means such as a dichroic prism and a plurality of image capturing elements may be used. Accordingly, light components of a plurality of different wavelengths may be detected from the light from the measurement pattern 72 using the image capturing element 75.

The controller 11 can acquire the position of the measurement pattern 72 based on the position information of the substrate stage WS obtained by the laser interferometer 13 and a signal waveform obtained by detecting the image of the measurement pattern 72. The strength of the signal waveform can be adjusted by at least one of control of the light amount adjustment unit (ND filter) provided in the illumination optical system of the image capturing unit 50, output control of the light source 61, and control of the accumulation time of the image capturing element 75.

Note that in the imaging system of the image capturing unit 50, a detection aperture stop may be formed by arranging a plurality of lenses between the polarization beam splitter 68 and the image capturing element 75. Also, a plurality of aperture stops capable of setting different numerical apertures for the illumination system and the imaging system may be provided in each of the illumination aperture stop 64 and the detection aperture stop, and the plurality of aperture stops may be switched. This makes it possible to adjust a σ value that is a coefficient representing the ratio of the numerical aperture of the illumination system and the numerical aperture of the imaging system. In addition, as a method of detecting the light from the measurement pattern 72, dark field detection may be used in which, for example, the aperture diameter of the illumination aperture stop 64 or the detection aperture stop is controlled, 0th-order diffracted light from the measurement pattern 72 is shielded, and only high order diffracted light or scattered light is detected.

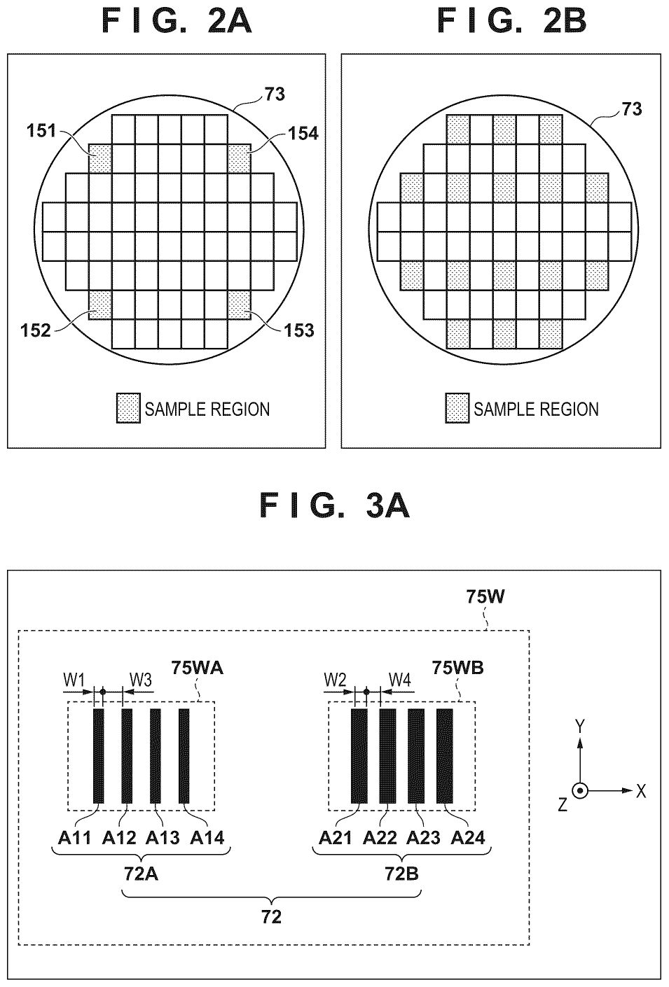

A method of capturing the measurement pattern formed on the substrate 73 and measuring the position of the substrate 73 using the measuring apparatus 100 will be described below. FIGS. 2A and 2B are views showing sample regions of a plurality of shot regions formed on the substrate 73. Position measurement for a measurement pattern is performed for a measurement pattern existing in each sample region. Here, a sample region means a region including both a region where a device pattern is formed and a region including scribe lines near that region. Selection of sample regions shown in FIGS. 2A and 2B is merely an example, and the number and positions of sample regions can arbitrarily be changed in accordance with the required substrate position measurement accuracy and throughput.

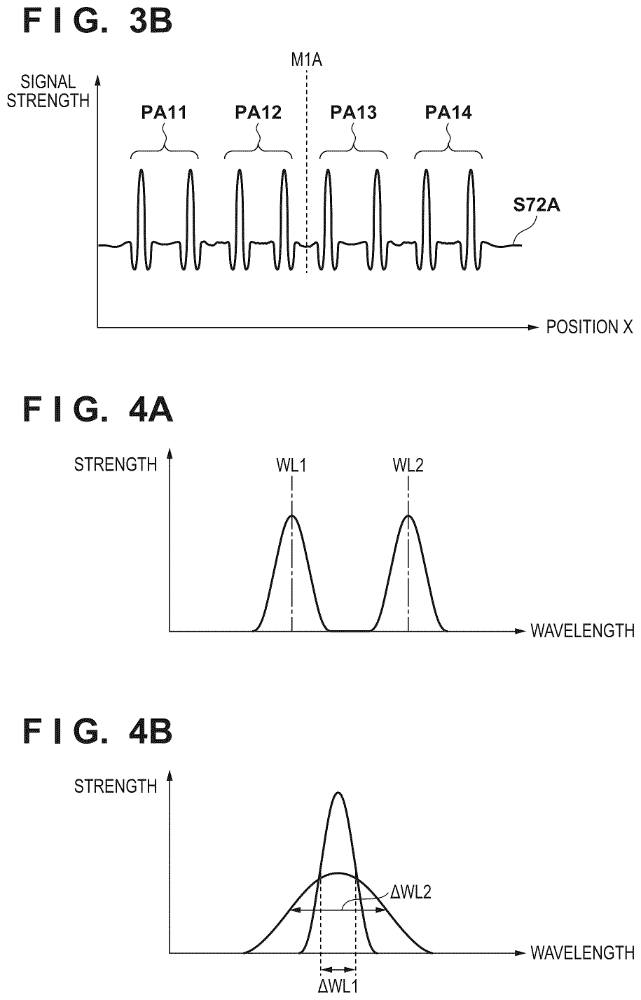

FIG. 3A is a view showing an example of the measurement pattern 72 formed on the substrate 73. The measuring apparatus 100 normally acquires position information in the X direction and the Y direction for the substrate 73. For the sake of simplicity, a description will be made here using only X patterns for measuring the position in the X direction.

In this embodiment, the measurement pattern 72 can include a plurality of different patterns. Measurement patterns 72A and 72B can be patterns (line-and-space patterns) formed by a plurality of line elements. For example, the measurement pattern 72 can include a measurement pattern 72A formed by line elements A11 to A14 and a measurement pattern 72B formed by line elements A21 to A24. A line-and-space pattern can have spaces between adjacent line elements. For example, as shown in FIG. 3A, the measurement patterns 72A and 72B have configurations in which line elements having widths W1 and W2 and spaces having widths W3 and W4 are periodically repeated. The width of at least one of the line element and the space is different between the measurement patterns 72A and 72B. Not only the widths of the line element and the space but also at least one of the pattern design, the number of patterns, the formation position in the Z direction on the substrate is preferably different. Note that the number of measurement patterns 72 is not limited to a specific number, and three or more measurement patterns may be formed.

In FIG. 3A, a region 75W indicates an image capturing region in the image capturing element 75 of the image capturing unit 50. As for the region 75W, the substrate 73 is aligned to the image capturing unit 50 such that the measurement pattern 72 is fitted in the region 75W. Light components from the plurality of different measurement patterns can thus simultaneously be detected. Coarse measurement is performed for the measurement pattern 72, and the controller 11 sets a plurality of different processing regions in the image capturing element 75 based on the result of the coarse measurement. Hence, for example, when processing regions 75WA and 75WB are set for the measurement patterns 72A and 72B, respectively, and measurement is performed, position information can be acquired for each of the measurement patterns 72A and 72B.

FIG. 3B is a view showing a result obtained by capturing the measurement pattern 72A by the image capturing element 75 and photoelectrically converting the signal strength in the X direction on the image capturing element surface (not shown). Reference numeral S72A indicates signal strength information including peak signals PA11 to PA14 of which two peak signals correspond to each of the line elements A11 to A14. A measurement value MIA of the measurement pattern 72A with respect to the reference position of the image capturing element 75 can be obtained from the signal strength information S72A. For the measurement pattern 72B, a measurement value M2A of the measurement pattern 72B can similarly be obtained. Note that the measurement value MIA is not limited to a measurement value with respect to the reference position of the image capturing element 75 and, for example, a position with respect to a preset measurement template or design value may be obtained as the measurement value.

Measurement parameters will be described next. The measuring apparatus 100 can preferably execute measurement in accordance with a set parameter value of at least one parameter. The at least one measurement parameter can include at least one of the central wavelength, the bandwidth of the wavelength, the σ value, and the polarization property of light (measurement light) to illuminate the measurement pattern. The polarization property can be the polarization property in the optical path of the measuring apparatus 100 or the measuring unit. The at least one measurement parameter may include various kinds of arithmetic processing parameters that are set when the controller 11 calculates a measurement value from the image information of the measurement pattern.

Measurement parameters concerning the wavelength of light used for measurement will be described below as an example. As the measurement parameters concerning the wavelength of light used for measurement, for example, a wavelength and the bandwidth of the wavelength can be exemplified. FIG. 4A is a view showing the wavelength characteristics of light components having different central wavelengths, and the two different central wavelengths are indicated by WL1 and WL2. FIG. 4B is a view showing the wavelength characteristics of light components that have the same central wavelength but different bandwidths of wavelengths, and the two different bandwidths of the wavelengths are indicated by AWL1 and AWL2.

The characteristics, for example, the physical property of the material, the structure, the shape, and the like of the measurement pattern on the substrate can vary in accordance with processes employed to obtain the substrate. Hence, to implement accurate measurement, it is important to match the measurement parameters with the characteristics of the measurement pattern.

However, the characteristic of the measurement pattern can locally change. For example, the characteristic of the measurement pattern changes in accordance with the measurement pattern or a feature part (pattern feature) forming the measurement pattern. Even if the central wavelength WL1 is the optimum measurement parameter value for the line element A11, for the line element A14, the central wavelength WL1 is not necessarily the optimum measurement parameter value. For this reason, when performing measurement using the measurement pattern 72 as a processing region, it is difficult to accurately determine the optimum value of the measurement parameter value.

In this embodiment, first, preliminary measurement for obtaining signal information obtained by detecting an image of a target formed on a substrate is performed a plurality of times while changing the parameter value of the measurement parameter (preliminary measurement). After that, the relationship between the parameter value and the signal information is acquired based on the result of preliminary measurement performed a plurality of times. Next, a processing region in the substrate where main measurement should be performed is determined based on the obtained relationship. Main measurement is then performed for the determined processing region.

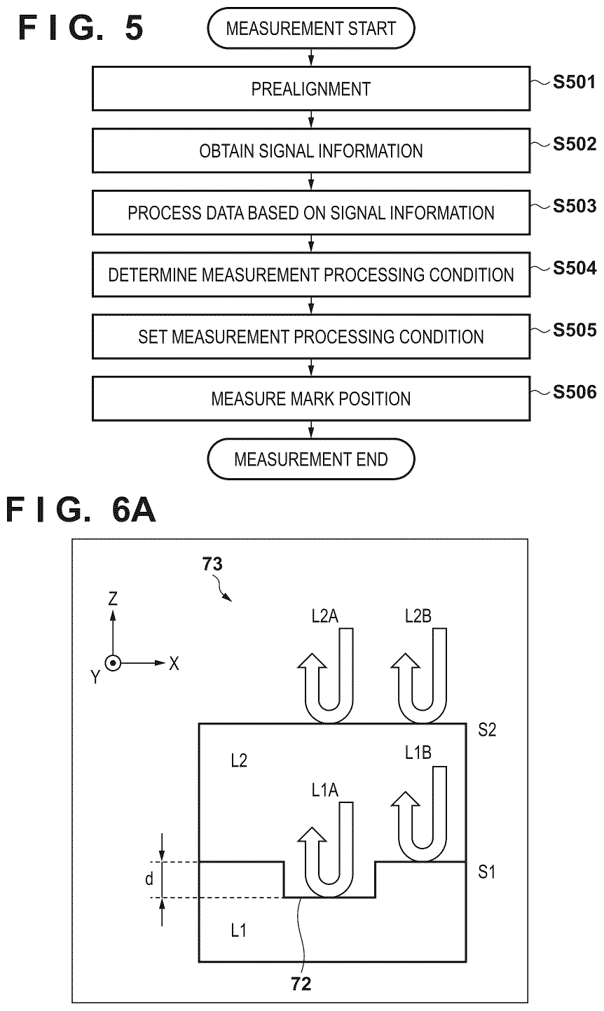

The sequence of measurement processing according to this embodiment will be described below with reference to FIG. 5. The measurement processing is performed by the controller 11 comprehensively controlling the units of the measuring apparatus 100.

In step S501, the controller 11 conveys the substrate 73 to the measurement range of the image capturing unit 50 and performs prealignment of the substrate 73 such that traveling of the substrate stage WS in the X direction matches the array direction of a plurality of shot regions exposed on the substrate 73 in the X direction.

In step S502, the controller 11 acquires signal information from the measurement pattern 72 while changing at least one measurement parameter. Here, the signal information can be at least one of a contrast, signal strength information, and position information, which are signal evaluation values obtained from an image. The signal evaluation values will be described later.

In step S503, the controller 11 obtains the data of signal information with respect to the change of the measurement parameter obtained in step S502. The data of signal information with respect to the change of the measurement parameter will be described later.

In step S504, the controller 11 can determine a measurement processing condition based on the data obtained in step S503. The measurement processing condition can be for example, at least one of a processing region, a sample region, and a measurement parameter. Here, the processing region is a processing region corresponding to a line element. For example, a plurality of processing regions may be set in accordance with the number of line elements. In this case, a weight to be added to each processing region can also be determined. Even for a plurality of different measurement patterns, processing regions may similarly be set, and weights to be added may be determined.

In step S505, the controller 11 sets a measurement processing condition in accordance with the measurement processing condition determined in step S504. Setting of the measurement processing condition is done by, for example, storing the measurement processing condition in a predetermined area of the storage unit.

In step S506, the controller 11 acquires the position information of the measurement pattern 72, and statistically processes the position information, thereby calculating the position of the substrate 73.

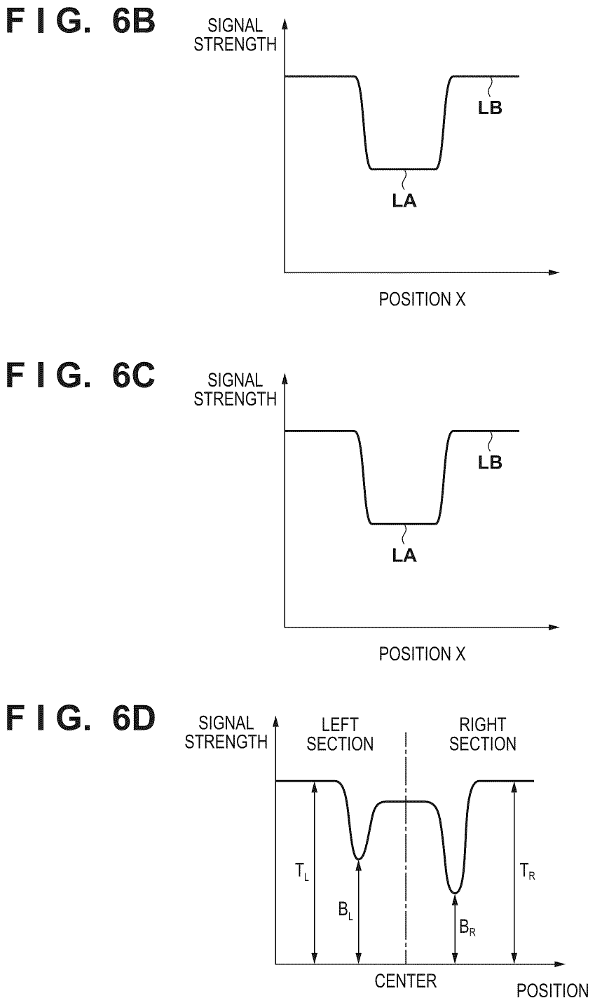

The signal evaluation values will be described below. A signal evaluation value means an index indicating the quality of signal strength information generated based on the output of the image capturing element 75 (image capturing unit 50). FIG. 6A is a view exemplarily showing reflected light components from the measurement pattern 72 and a non-pattern portion on a cross section of the substrate 73. The substrate 73 is formed by a first layer L1 and a second layer L2 and includes two boundary surfaces S1 and S2. On the boundary surface S1, the measurement pattern 72 has a step with a height d with respect to the non-pattern portion. Let LIA be reflected light from the measurement pattern 72 on the boundary surface S1, LIB be reflected light from the non-pattern portion, and L2A and L2B be reflected light components from the measurement pattern 72 and the non-pattern portion on the boundary surface S2. In the image capturing unit 50, interference light between the reflected light LIA and the reflected light L2A and interference light between the reflected light LIB and the reflected light L2B are reflected light LA from the measurement pattern 72 and reflected light LB from the non-pattern portion, and each light is detected.

FIG. 6B is a view showing an example of the signal strength information with respect to a position X, and includes the reflected light LA from the pattern portion and the reflected light LB from the non-pattern portion shown in FIG. 6A. Here, the smaller the signal strength difference between the reflected light LA and the reflected light LB is, the lower the signal contrast is, and the more difficult detecting the position of the measurement pattern is. The signal strength difference between the reflected light LA and the reflected light LB changes in accordance with a phase difference Δ caused by the step d of the measurement pattern 72. The phase difference Δ is represented by equation (1) below using a refractive index n of the second layer L2, the step d, and a wavelength λ.

$$Δ = 2 nd \times 2 π / λ \qquad ( 1 )$$

According to equation (1), if the refractive index n of the second layer L2 or the step d varies in the measurement pattern 72, the phase difference Δ changes. As described above, the change of the phase difference Δ leads to the change of the signal contrast, and along with this, a measurement error may occur, and the measurement accuracy may lower.

FIG. 6C is a view showing an example of the signal strength information of the pattern. The abscissa means the position, and the ordinate means the signal strength. Because of the difference of the structure on the substrate between the pattern portion and the non-pattern portion, the signal strength changes in accordance with the position of each portion. One of the pieces of characteristic information of the measurement pattern is a value obtained by quantifying the contrast of the measurement signal.

For example, in FIG. 6C, let TL be the maximum value of the signal strength in the left section of the measurement signal, BL be the minimum value, T_{R} be the maximum value of the signal strength in the right section, and BR be the minimum value. A contrast EC in the measurement signal may be obtained as characteristic information, as indicated by equation (2) below.

$$EC = \{ ( {T}_{L} - {B}_{L} ) / ( {T}_{L} + {B}_{L} ) + ( {T}_{R} - {B}_{R} ) / ( {T}_{R} + {B}_{R} ) \} / 2 \qquad ( 2 )$$

In addition, for example, asymmetry ES of the measurement signal as shown in FIG. 6D may be obtained as characteristic information. The asymmetry of the measurement signal can be calculated in accordance with equation (3) below.

$$ES = ( {T}_{L} - {B}_{L} ) / ( {T}_{L} + {B}_{L} ) - ( {T}_{R} - {B}_{R} ) / ( {T}_{R} + {B}_{R} ) \qquad ( 3 )$$

The asymmetry calculation method is not limited to equation (3) and, for example, the center position of the measurement signal may be defined, and the asymmetry of the measurement signal may be defined based on the signal strength in a predetermined position range in each of the left section and the right section with respect to the center position.

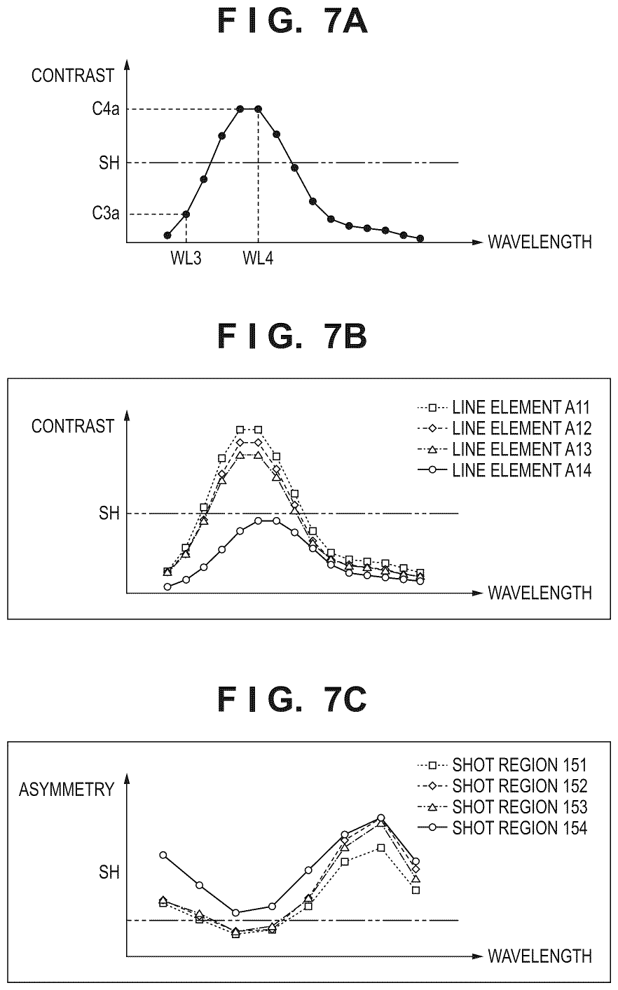

A measurement processing condition determination method based on the relationship between a measurement parameter and signal information in steps S503 and S504 will be described below with reference to FIGS. 7 and 8. First, as an example, a measurement processing condition determination method in a case where the measurement parameter is the central wavelength, and the signal information is the contrast of each of a plurality of line elements will be described. Here, an example in which a processing region is determined as a measurement processing condition will be described. The data of the contrast with respect to the change of the central wavelength is an index used to determine the measurement processing condition to be employed in measurement in step S507.

FIG. 7A is a view showing the relationship between a contrast that is the signal information of the measurement pattern 72A obtained in the processing region 75WA (FIG. 3A) and the central wavelength. The abscissa represents the central wavelength (to be referred to as “wavelength”), and the ordinate represents the contrast of the measurement pattern 72A. Here, a central wavelength WL3 and a central wavelength WL4 each mean the central wavelength of light. According to FIG. 7A, the contrast of the measurement pattern 72A at the central wavelength WL3 is C3a, and the contrast at the central wavelength WL4 is C4a. Here, the contrast of the measurement pattern 72A is a result of averaging contrast values obtained by the peak signals PA11 to PA14 (FIG. 3B). Then, for example, it is determined whether (the maximum value of) the obtained contrast value exceeds a threshold SH. The threshold SH can be determined using the characteristic information or position information of a plurality of substrates obtained in advance. When the measurement parameter value is selected in the above-described way, measurement errors associated with process changes can be reduced. If the measurement parameter value is selected based on not the signal information but the position information of the measurement pattern, a parameter value for which the sensitivity indicating the change of the measurement value with respect to the change of the measurement parameter is small may be selected.

FIG. 7B is a view showing the relationship between the central wavelength and the contrast for each of the line elements A11 to A14 of the measurement pattern 72A. Even in the same measurement pattern, film unevenness or shape difference for each pattern may be caused by the processes. Hence, even for each of the plurality of line elements, it is necessary to determine whether (the maximum value of) the contrast value exceeds the threshold SH. According to FIG. 7B, the contrast values (for example, the maximum contrast values) of the line elements A11, A12, and A13 exceed the threshold SH, but the contrast value of the line element A14 is less than the threshold SH. Hence, a region except the line element A14 is set to a processing region (as a measurement processing condition), like a processing region 75WC shown in FIG. 8. Here, as an example, the plurality of line elements have been described. However, a processing region may be set for each of a plurality of measurement patterns or device patterns in which the pattern design, the number of line elements, or the formation position in the Z direction on the substrate changes.

In the above-described determination method, the target has a pattern including a plurality of line elements, the measurement parameter is the central wavelength of light that illuminates the measurement pattern, and the signal information is the contrast of each of the plurality of line elements. In the determination method, the relationship between the central wavelength and the contrast is acquired for each of the plurality of line elements. Of the plurality of line elements, a line element for which the maximum value of the contrast is smaller than the threshold in the relationship is excluded from the targets of main measurement.

### (Sample Region Determination Method)

A method of determining a processing region as a measurement processing condition in a case where the measurement parameter is the central wavelength, and the signal information is the contrast has been described above. Next, a method of determining a sample region as a measurement processing condition in a case where the measurement parameter is the central wavelength, and the signal information is the asymmetry of a measurement signal will be described. Here, a plurality of targets are patterns each formed by a plurality of line elements and are arranged in each of a plurality of predetermined shot regions set as sample region candidates on the substrate 73.

FIG. 7C is a view showing the relationship between the central wavelength and the asymmetry of the measurement signal, which is obtained in each of shot regions 151 to 154 (FIG. 2A). The abscissa represents the central wavelength, and the ordinate represents the asymmetry of the measurement signal. The asymmetry of the measurement signal in each sample region causes measurement deception and is therefore preferably small. It is determined whether the magnitude of the asymmetry of the measurement signal does not exceed the threshold SH, and sample regions are set based on the determination result. For example, in FIG. 7C, the minimum value of the asymmetry of the measurement signal in the shot region 154 exceeds the threshold SH. For this reason, the shot region 154 is excluded from the sample regions.

By performing the determination method as described above, measurement errors associated with process changes can be reduced, and accurate position measurement can be achieved.

Processing in a case where weights to be added to the line elements A11 to A14 shown in FIG. 8 when calculating the position of the measurement pattern 72 are set as the measurement processing conditions will be described below. Here, the position of the pattern is represented by the weighted average of the positions of the plurality of line elements. For example, letting N11 to N14 be the weight coefficients to the pattern positions (PA11 to PA14) and P72A be the position of the measurement pattern 72A, the position P72A of the measurement pattern 72A can be calculated by

$$P 72 A = ( N 11 \cdot PA 11 + N 12 \cdot PA 12 + N 13 \cdot PA 13 + N 14 \cdot PA 14 ) / 4 \qquad ( 4 )$$

Alternatively, for example, weights may be added to the plurality of different measurement patterns 72A and 72B that form the measurement pattern 72. Furthermore, weights may be added to a plurality of measurement patterns 72 formed at different positions on the substrate. This makes it possible to accurately obtain the position of the measurement pattern regardless of process changes in the region of the measurement pattern 72 or at the position on the substrate.

According to the above-described determination method, the relationship between the central wavelength and the asymmetry of the measurement signal is acquired for each of the plurality of predetermined shot regions that are sample region candidates. Of the plurality of predetermined shot regions, a shot region for which the minimum value of the asymmetry in the relationship exceeds the threshold is excluded from the sample region candidates.

As one of methods of calculating a weight coefficient, a method based on an acquired overlay measurement value will be described below.

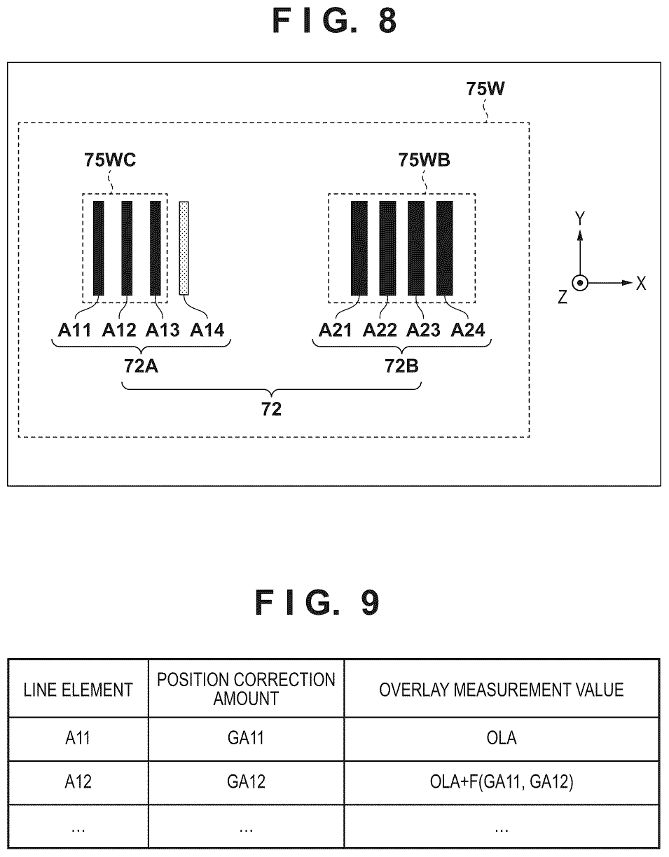

FIG. 9 is a view showing the relationship between a pattern, the position correction amount (position correction coefficient) of the substrate 73 based on the pattern, and the overlay measurement value of the formed pattern. For example, a position correction amount GA11 of the substrate means a result calculated by executing global alignment based on the position measurement result of the line element A11. Also, an overlay measurement value OLA means a result acquired by forming a pattern on the substrate based on the position correction amount GA11 of the substrate.

Note that when the position measurement result of the pattern A12 is used, an overlay measurement value OLB can be estimated from the following equation based on the position correction amounts GA11 and GA12 of the substrate and the overlay measurement value OLA.

$$OLB = OLA + F ( GA 11 , GA 12 ) \qquad ( 5 )$$

Here, F (GA11, GA12) indicates a function including GA11 and GA12. As a typical example, F (GA11, GA12) can be GA11-GA12. In this case, the overlay measurement value OLB is calculated as a value obtained by adding the difference value between the position correction amounts GA11 and GA12 of the substrate to the overlay measurement value OLA. Detailed examples of the position correction amount are the position deviation (shift) of the substrate, a magnification error, and a rotation error. In arithmetic processing, it is preferable to calculate the difference value between the position correction amounts and add the difference value between the position correction amounts to the plurality of shot regions on the substrate 73.

In the measuring apparatus according to this embodiment, a processing region is set for each of the plurality of line elements that form the measurement pattern in the image capturing region obtained from the image capturing unit 50, and the position of the substrate is measured. Then, based on the measurement value acquired for each processing region, the position correction amount of the substrate is calculated. Hence, the position correction amount of the substrate according to the plurality of different processing regions is calculated, and the overlay measurement value according to the plurality of different processing regions can be estimated based on the position information of the pattern formed on the substrate.

The weight coefficient to be added to each processing region (that is, each line element in the measurement pattern) is preferably determined such that the overlay measurement value for each of the plurality of shot regions on the substrate is not more than an allowable value (for example, minimum). A weight may be set as a parameter, and a weight coefficient with which the overlay measurement value is not more than an allowable value (for example, minimum) may be calculated. In an example, setting a processing region including only one of the plurality of line elements included in the measurement pattern is performed by setting the weight coefficient to the one line element to 1 and setting the weight coefficients to the remaining line elements to 0. Note that not a positive number but a negative number may be given to the weight coefficient.

As still another method, the difference value between the acquired position information of the pattern and the design value (target value) may be obtained, and the weight coefficient may be set such that the difference value is minimum. As yet another method, the weight coefficient may be set based on the acquired signal information of the measurement pattern and the number of line elements. Furthermore, the weight coefficient may be set such that variations of the signal information in the plurality of shot regions on the substrate 73 are minimized.

Here, in step S505, the weight coefficients added to the plurality of line elements that form the measurement pattern need not always be identical to all sample regions on the substrate 73. For example, the setting of the weight coefficient may be changed in accordance with the position of the sample region with respect to the substrate 73. The weight coefficients need not always be identical concerning measurement directions on the substrate 73. For example, different weight coefficients may be set for measurement in the X direction and measurement in Y direction. In this way, the weight coefficients for the plurality of line elements that form the measurement pattern are determined.

Concerning pattern position measurement in step S506, detailed statistical processing will be described. For example, the positions of the plurality of shot regions formed on the substrate 73 may be calculated by performing global alignment measurement based on the position information of the measurement pattern in the plurality of sample regions.

In this embodiment, pattern position measurement can be executed by the controller 11. However, the invention is not limited to this. For example, pattern position measurement may be executed by an online host apparatus that controls other apparatus in a factory, where the measuring apparatus 100 is installed, in an integrated manner, via a network. In addition, the position measurement result may be, for example, transferred, via the online host, to an exposure apparatus that performs exposure as the next process of the substrate 73.

As described above, in the first embodiment, light from a pattern formed on a substrate is captured, the relationship between a measurement parameter and signal information is acquired, and a measurement processing condition is determined based on the obtained relationship. The position of the substrate is calculated in accordance with the above-described measurement processing condition, thereby accurately measuring the measurement target object.

### Second Embodiment

As the second embodiment, a measuring apparatus and method for measuring the quality of a measurement pattern formed on a substrate or a line element that forms the measurement pattern will be described.

The function of the measuring apparatus (measurement pattern monitor) will be described first. To accurately align a substrate 73 and form a device pattern at a desired position, it is important to detect the presence/absence of a change in the characteristic information (a shape, structure, physical property value, and the like) of the substrate. If the characteristic of the substrate changes more than assumed, the measurement value of the measurement pattern may change, and the alignment accuracy of the substrate or the overlay accuracy of the pattern on the substrate may lower. To prevent this, the measuring apparatus measures (monitors) the characteristic of the measurement pattern or the pattern and detects the presence/absence of an abnormality in the substrate. Upon detecting an abnormality in the substrate, the measuring apparatus can make a warning or an error notification.

Note that the measurement pattern formed on the substrate in this embodiment is not limited to an alignment pattern or an overlay measurement pattern and may be, for example, a device pattern.

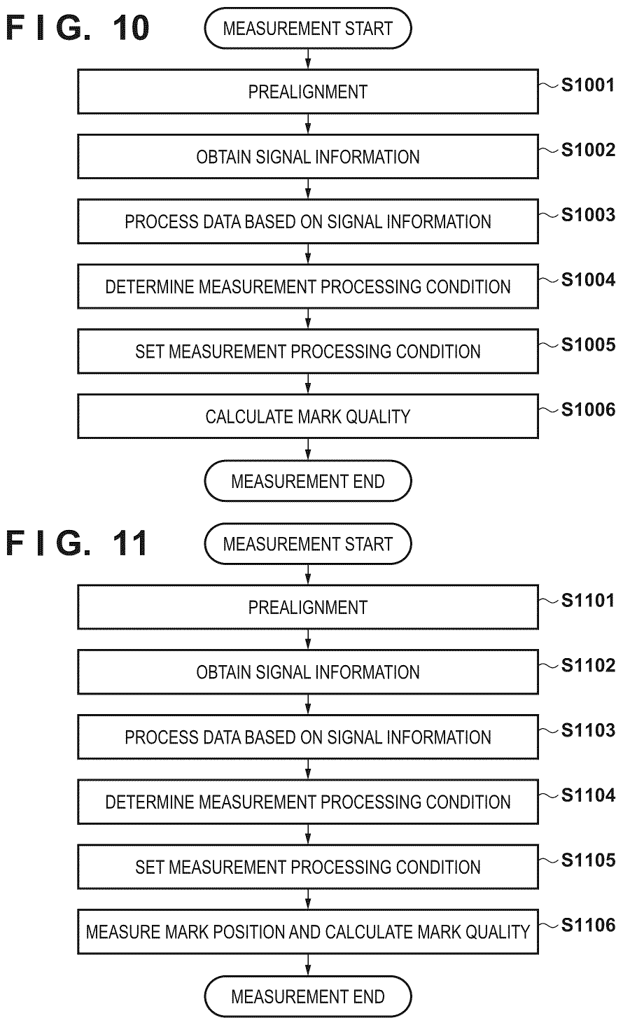

Measurement processing according to the second embodiment will be described with reference to FIG. 10. The difference between the second embodiment and the first embodiment is that the signal information of the measurement pattern formed on the substrate is acquired, and comparison and determination are performed, and this point will be described in detail. The rest of the configuration is the same as in the first embodiment, and a description thereof will be omitted. Matters that are not mentioned here can comply with the first embodiment. Steps S1001 to S1006 shown in FIG. 10 are the same as steps S501 to S506 shown in FIG. 5, and a description thereof will be omitted here.

In step S1006, a controller 11 acquires the signal information of a measurement pattern 72, obtains a difference (pattern quality) from reference data, and determines whether the difference is not more than an allowable value. As the reference data, data based on the characteristic information or position information of a plurality of substrates obtained in advance may be used. As the allowable value, a value based on variation amounts in a plurality of substrates obtained in advance or the shape (distortion of a grid) of a substrate necessary for achieving the object of overlay may be set.

In the measurement pattern monitor according to the second embodiment, the measurement processing condition determination method is different from the first embodiment. To set a measurement processing condition for accurately detecting a characteristic change of a substrate, signal information to be acquired preferably sensitively changes with respect to the characteristic change of the substrate. In the measurement processing condition determination method according to this embodiment, the measurement processing condition is set such that the variation of the asymmetry or contrast of a measurement signal is maximized in a plurality of sample regions on the substrate. Here, the measurement processing condition can be a measurement parameter, a processing region, or a weight coefficient to each of a plurality of line elements that forms the measurement pattern. The measurement processing condition may be selected such that a sensitivity indicating a change of a measurement value with respect to a change of a measurement parameter becomes large.

The obtained pattern quality or distortion of a grid may be transferred (fed back) to an apparatus that performs known processes (oxidation, film formation, deposition, doping, planarization, resist removal, and the like) via, for example, an online host, thereby performing quality management.

As described above, in the second embodiment, light from a pattern formed on a substrate is captured, the relationship between a measurement parameter and signal information is acquired, and a measurement processing condition sensitive to a characteristic change of the substrate is determined based on the obtained relationship. Thus, the pattern quality can be detected at a high accuracy.

### Third Embodiment

As the third embodiment, a measuring method for executing position measurement of a substrate and quality monitor of a pattern formed on the substrate will be described.

The function of a measuring apparatus (measurement pattern monitor) will be described first. As described above, to accurately align a substrate 73 and form a device pattern at a desired position, it is important to
select a measurement parameter value that minimizes a measurement error associated with process changes and
detect the presence/absence of a change in the characteristic information (a shape, structure, physical property value, and the like) of the substrate.

The measuring method according to the third embodiment will be described with reference to FIG. 11. The difference between the third embodiment and the first and second embodiments is that accurate alignment measurement and measurement pattern monitor are simultaneously performed, and this point will be described in detail. The rest of the configuration is the same as in the first and second embodiments, and a description thereof will be omitted here. Matters that are not mentioned here can comply with the first and second embodiments.

FIG. 11 is a view showing the measurement sequence according to the third embodiment. Steps S1101 to S1105 shown in FIG. 11 are the same as steps S501 to S505 shown in FIG. 5, and a description thereof will be omitted here.

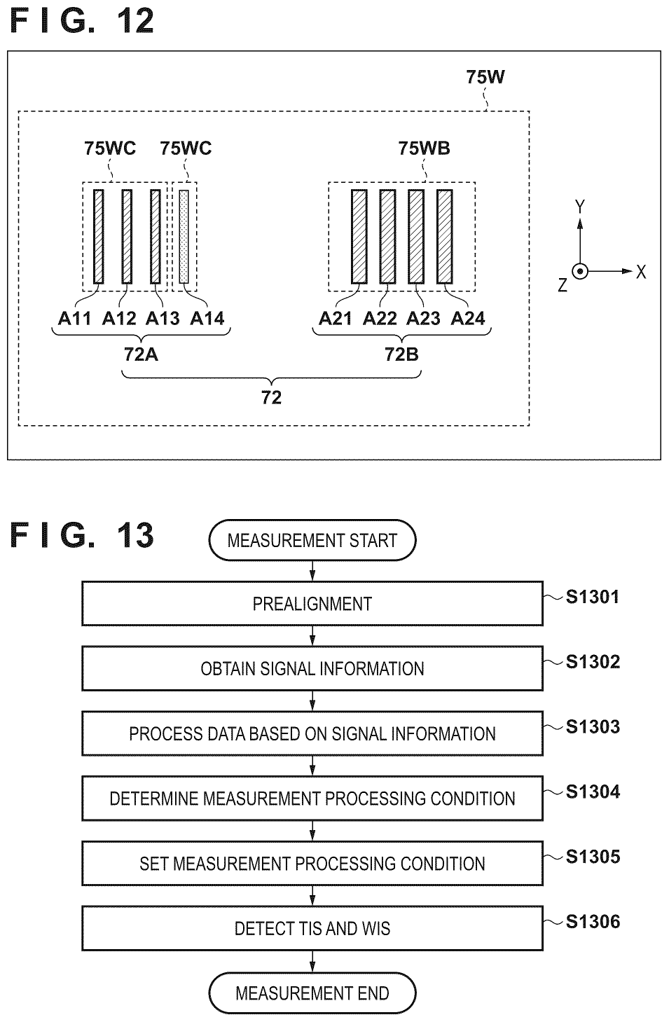

In step S1106, the signal information of a measurement pattern 72 is acquired, and substrate position measurement and determining whether the pattern quality falls within an allowable range are performed in parallel. In the third embodiment, as the measurement processing condition, a condition insensitive to the characteristic change of the substrate and a condition sensitive to it need to be set. For example, as shown in FIG. 12, a processing region 75WC is set to a region including only an (insensitive) pattern for which a measurement error associated with a process change is small. On the other hand, a processing region 75WC′ is set to a region including only a (sensitive) pattern for which a measurement error associated with a process change is large. In this way, when the signal information obtained from the processing region 75WC is used, the position of the measurement pattern can accurately be measured. When the signal information obtained from the processing region 75WC′ is used, the quality of the pattern can accurately be detected.

As described above, in the third embodiment, light from a pattern formed on a substrate is captured, the relationship between a measurement parameter and signal information is acquired, and a measurement processing condition sensitive to a characteristic change of the substrate and a measurement processing condition insensitive to it are set based on the obtained relationship. This makes is possible to simultaneously and accurately execute substrate position measurement and pattern quality detection.

### Fourth Embodiment

As the fourth embodiment, a measuring method for detecting a measurement error (TIS) derived from a measuring apparatus and a measurement error (WIS) caused by the characteristic of a pattern formed on a substrate will be described.

TIS and WIS will be described. TIS is an error that occurs due to an aberration of a measuring apparatus or the like, and does not depend on the direction of a substrate. On the other hand, WIS is a measurement error caused by the shape, structure, physical property value of a pattern formed on a substrate and, therefore, the sign changes depending on the direction of the substrate. To accurately align a substrate 73 and form a device pattern at a desired position, it is important to detect the presence/absence of a change of TIS and WIS.

The measuring method according to the fourth embodiment will be described below with reference to FIG. 13. The difference between the fourth embodiment and the first embodiment is that the signal information of the pattern is acquired while changing the position of the substrate. This point will be described in detail. The rest of the configuration is the same as in the first embodiment, and a description thereof will be omitted here. Matters that are not mentioned here can comply with the first embodiment.

FIG. 13 is a view showing a measurement sequence according to the fourth embodiment. Steps S1301 and S1303 to S1305 shown in FIG. 13 are the same as steps S501 and S503 to S505 shown in FIG. 5, and a description thereof will be omitted here.

In step S1302, a controller 11 can acquire the signal information of a measurement pattern 72 on the substrate 73 a plurality of times by an image capturing element 75 (image capturing unit) while changing at least one measurement parameter. The plurality of times of measurement can include measurement at positions of the substrate in the rotation direction, for example, at 0° and 180° positions of the substrate.

In step S1306, the signal information of the measurement pattern 72 is acquired, at least one of TIS and WIS is removed, the difference from reference data is obtained, and it is determined whether the allowable value is achieved. As the reference data, the characteristic information or position information of a plurality of substrates obtained in advance may be used. As the allowable value, variation amounts in a plurality of substrates obtained in advance or the shape of a substrate necessary for achieving the object of overlay may be set.

A TIS/WIS detection operation method according to the fourth embodiment will be described below.

Let M0 and M180 be the measurement values obtained by rotating the substrate to the positions of 0° and 180° and obtaining the position of the pattern. Also, let TWI0 and TWI180 be the errors that occur due to the interaction between TIS and WIS and a position deviation amount Shift at the time of substrate conveyance. At this time, the measurement values M0 and M180 are given by

$$M 0 = Shift + TIS + WIS + TWI 0 \qquad ( 6 )$$

$$M 180 = - Shift + TIS - WIS + TWI 180 \qquad ( 7 )$$

To detect TIS, arithmetic processing is performed to remove WIS. Hence, a measurement value MTIS when detecting TIS is given by

$$MTIS = Shift + TIS + ( TWI 0 - TWI 180 ) / 2 \qquad ( 8 )$$

According to equation (8), TIS can accurately be detected, as compared to equations (6) and (7).

On the other hand, to detect WIS, arithmetic processing is performed to remove TIS. Hence, a measurement value MWIS when detecting WIS is given by

$$MWIS = Shift + WIS + ( TWI 0 - TWI 180 ) / 2 \qquad ( 9 )$$

According to equation (9), WIS can accurately be detected, as compared to equations (6) and (7).

As described above, in the fourth embodiment, light from a pattern formed on a substrate is captured, the relationship between a measurement parameter and signal information is acquired, and a measurement processing condition sensitive to a characteristic change of the substrate is set based on the obtained relationship. Furthermore, arithmetic processing of the signal information at different substrate positions is performed, thereby accurately detecting TIS and WIS.

### <Embodiment of Lithography Apparatus Including Measuring Apparatus>

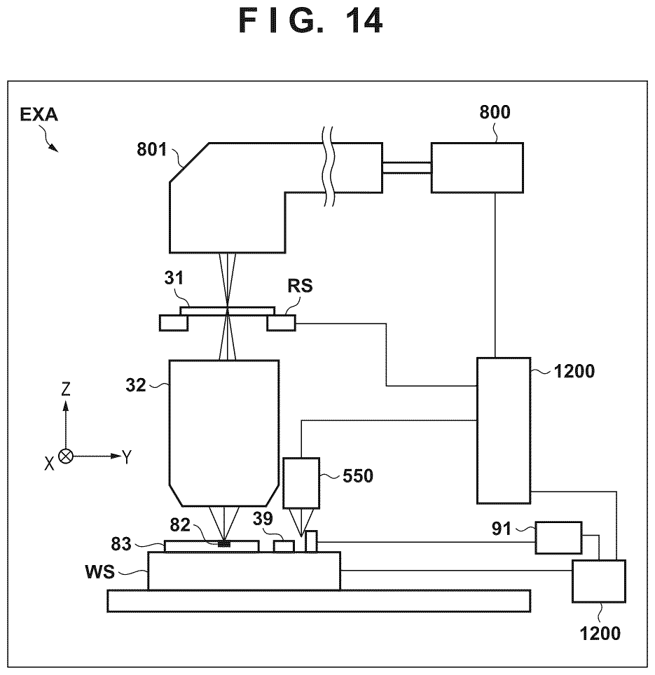

A lithography apparatus incorporating the above measuring apparatus will be described below. The lithography apparatus can be an apparatus that transfers a pattern on a substrate, for example, an exposure apparatus, an imprint apparatus, or an electron beam drawing apparatus. FIG. 14 is a schematic view showing the configuration of an exposure apparatus EXA as an example of the lithography apparatus. The exposure apparatus EXA is a lithography apparatus which is used in a lithography process as a manufacturing process of an article or a device such as a semiconductor device or a liquid crystal display device and forms a pattern on a substrate 83. The exposure apparatus EXA exposes the substrate 83 via a reticle 31 serving as an original, thereby transferring the pattern of the reticle 31 to the substrate 83. In this embodiment, the exposure apparatus EXA employs a step-and-scan method, but it can also employ a step-and-repeat method or other exposure methods.

As shown in FIG. 14, the exposure apparatus EXA includes an illumination optical system 801, a reticle stage RS which holds the reticle 31, a projection optical system 32, a substrate stage WS which holds the substrate 83, a position measuring apparatus 550, and a controller 1200.

The illumination optical system 801 is an optical system that illuminates an illuminated surface using light from a light source unit 800. The light source unit 800 includes, for example, a laser. The laser includes an Arf excimer laser having a wavelength of about 193 nm, a KrF excimer laser having a wavelength of about 248 nm, or the like, but the type of light source is not limited to the excimer laser. For example, the light source unit 800 may use, as the light source, an F2 laser having a wavelength of about 157 nm or extreme ultraviolet (EUV) having a wavelength of 20 nm or less.

In this embodiment, the illumination optical system 801 shapes the light from the light source unit 800 into slit light having a predetermined shape suitable for exposure, and illuminates the reticle 31.

The illumination optical system 801 has a function of uniformly illuminating the reticle 31 and a polarizing illumination function. The illumination optical system 801 includes, for example, a lens, a mirror, an optical integrator, a stop, and the like, and is formed by arranging a condenser lens, a fly-eye lens, an aperture stop, a condenser lens, a slit, and an imaging optical system in this order.

The reticle 31 is formed of, for example, quartz.

The reticle 31 is formed with a pattern (circuit pattern) to be transferred to the substrate 83.

The reticle stage RS holds the reticle 31 via a reticle chuck (not shown), and is connected to a reticle driving mechanism (not shown). The reticle driving mechanism includes a linear motor or the like, and can move the reticle 31 held by the reticle stage RS by driving the reticle stage RS in the X direction, the Y direction, the Z direction, and the rotation directions about the respective axes. Note that the position of the reticle 31 is measured by a reticle position measuring unit of light oblique-incidence type (not shown), and the reticle 31 is arranged at a predetermined position via the reticle stage RS.

The projection optical system 32 has a function of imaging the light from an object plane in an image plane. In this embodiment, the projection optical system 32 projects the light (diffracted light) having passed through the pattern of the reticle 31 onto the substrate 83, thereby forming the image of the pattern of the reticle 31 on the substrate. As the projection optical system 32, an optical system formed from a plurality of lens elements, an optical system (catadioptric optical system) including a plurality of lens elements and at least one concave mirror, an optical system including a plurality of lens elements and at least one diffractive optical element such as kinoform, or the like is used.

A photoresist is applied onto the substrate 83. The substrate 83 is a processing target object to which the pattern of the reticle 31 is transferred, and includes a wafer, a liquid crystal substrate, another processing target substrate, or the like.

The substrate stage WS holds the substrate 83 via a substrate chuck (not shown), and is connected to a substrate driving mechanism (not shown). The substrate driving mechanism is a positioning mechanism that positions the substrate 83 based on the position of a mark measured using the position measuring apparatus 550. The substrate driving mechanism includes a linear motor or the like, and can move the substrate 83 held by the substrate stage WS by driving the substrate stage WS in the X direction, the Y direction, the Z direction, and the rotation directions about the respective axes. Further, a reference plate 39 is provided on the substrate stage WS.

The position of the reticle stage RS and the position of the substrate stage WS are monitored by, for example, a 6-axis laser interferometer 91 or the like, and the reticle stage RS and the substrate stage WS are driven at a constant speed ratio under the control of the controller 1200.

The controller 1200 is formed by a computer (information processing apparatus) including a CPU, a memory, and the like and, for example, operates the exposure apparatus EXA by comprehensively controlling respective units of the exposure apparatus EXA in accordance with a program stored in a storage unit.

The controller 1200 controls exposure processing of transferring the pattern of the reticle 31 to the substrate 83 by exposing the substrate 83 via the reticle 31. Further, in this embodiment, the controller 1200 controls measurement processing in the position measuring apparatus 550 and correction processing (arithmetic processing) of a measurement value obtained by the position measuring apparatus 550. In this manner, the controller 1200 also functions as a part of the position measuring apparatus 550.

In the exposure apparatus EXA, the light (diffracted light) having passed through the reticle 31 is projected onto the substrate 83 via the projection optical system 32. The reticle 31 and the substrate 83 are arranged in an optically conjugate relationship. The pattern of the reticle 31 is transferred to the substrate 83 by scanning the reticle 31 and the substrate 83 at a speed ratio of a reduction ratio of the projection optical system 32.

The position measuring apparatus 550 is a measuring apparatus for measuring the position of a target object. In this embodiment, the position measuring apparatus 550 measures the position of a mark 82 such as an alignment mark provided in the substrate 83. A wavelength variable unit 540 is constituted by a wavelength variable element and a holding member. The controller drives the wavelength variable unit 540 in the X direction by using a driving mechanism (not shown).

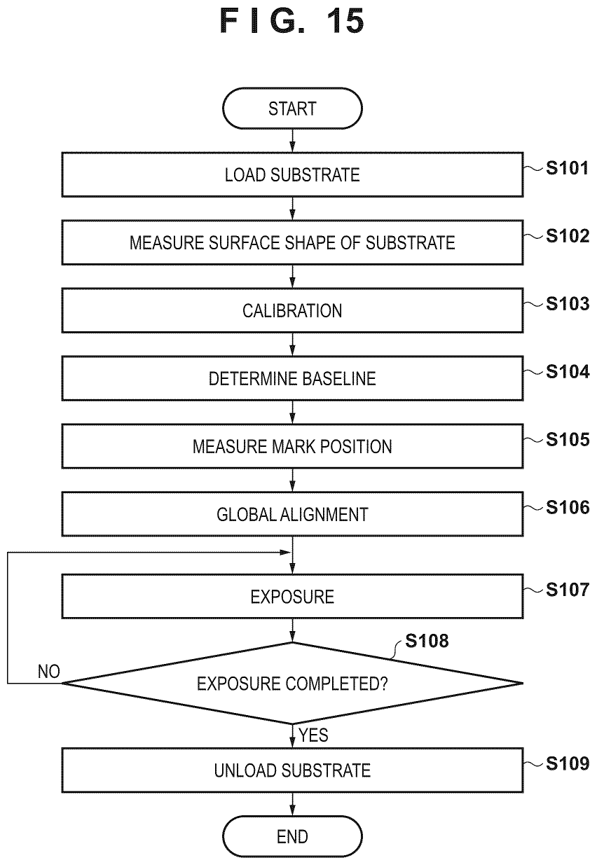

With reference to FIG. 15, the sequence of the exposure processing of transferring the pattern of the reticle 31 onto the substrate 83 by exposing the substrate 83 via the reticle 31 will be described. As has been described above, the exposure processing is performed by the controller 1200 comprehensively controlling the respective units of the exposure apparatus EXA.

In step S101, the substrate 83 is loaded in the exposure apparatus EXA. In step S102, the surface (height) of the substrate 83 is detected by a shape measuring apparatus (not shown) to measure the surface shape of the entire substrate 83.

In step S103, calibration is performed. More specifically, based on the designed coordinate position of the reference mark provided in the reference plate 39 in the stage coordinate system, the substrate stage WS is driven so as to position the reference mark on the optical axis of the position measuring apparatus 550. Then, the positional shift of the reference mark with respect to the optical axis of the position measuring apparatus 550 is measured, and the stage coordinate system is reset based on the positional shift such that the origin of the stage coordinate system coincides with the optical axis of the position measuring apparatus 550. Next, based on the designed positional relationship between the optical axis of the position measuring apparatus 550 and the optical axis of the projection optical system 32, the substrate stage WS is driven so as to position the reference mark on the optical axis of the exposure light. Then, the positional shift of the reference mark with respect to the optical axis of the exposure light is measured via the projection optical system 32 by a through the lens (TTL) measurement system.

In step S104, based on the result of calibration obtained in step S103, the baseline between the optical axis of the position measuring apparatus 550 and the optical axis of the projection optical system 32 is determined. In step S105, the position measuring apparatus 550 measures the position of the mark 82 provided in the substrate 83.

In step S106, global alignment is performed. More specifically, based on the measurement result obtained in step S105, the shift, the magnification, and the rotation with respect to the array of shot regions on the substrate 83 are calculated, and the regularity of the array of the shot regions is obtained. Then, a correction coefficient is obtained from the regularity of the array of the shot regions and the baseline, and the substrate 83 is aligned with the reticle 31 (exposure light) based on the correction coefficient.

In step S107, the substrate 83 is exposed while scanning the reticle 31 and the substrate 83 in a scanning direction (Y direction). At this time, based on the surface shape of the substrate 83 measured by the shape measuring apparatus, an operation of sequentially adjusting the surface of the substrate 83 to the imaging plane of the projection optical system 32 is also performed by driving the substrate stage WS in the Z direction and the tilt direction.

In step S108, it is determined whether exposure for all the shot regions of the substrate 83 is completed (that is, whether there is no unexposed shot region). If exposure for all the shot regions of the substrate 83 is not completed, the process returns to step S107, and steps S107 and S108 are repeated until exposure for all the shot regions is completed. On the other hand, if exposure for all the shot regions of the substrate 83 is completed, the process advances to step S109, and the substrate 83 is unloaded from the exposure apparatus EXA.

In this embodiment, the position of the mark 82 is measured by using each of a plurality of different measurement parameters, and the sensitivity of each measurement value corresponding to measurement parameter variations is calculated concerning at least two or more measurement parameters.

Measurement parameters to be used for measurement are determined based on the sensitivities. This makes it possible to reduce errors in alignment measurement and implement accurate alignment. Accordingly, this embodiment can provide a position measuring apparatus that can fast and accurately measure the positions of the patterns on a substrate.

### <Embodiment of Article Manufacturing Method>

An article manufacturing method of manufacturing an article by using the above lithography apparatus will be exemplarily described. The article manufacturing method is suitable for, for example, manufacturing an article such as a device (a semiconductor device, a magnetic storage medium, a liquid crystal display device, or the like). The manufacturing method includes a step of exposing, by using an exposure apparatus EXA, a substrate with a photosensitive agent applied thereon (forming a pattern on the substrate), and a step of developing the exposed substrate (processing the substrate). In addition, the manufacturing method can include other well-known steps (oxidation, film formation, deposition, doping, planarization, etching, resist removal, dicing, bonding, packaging, and the like). The article manufacturing method of this embodiment is more advantageous than the conventional methods in at least one of the performance, quality, productivity, and production cost of the article. Note that the above-described article manufacturing method may be performed by using a lithography apparatus such as an imprint apparatus or a drawing apparatus.

While the present disclosure has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2024-024827, filed Feb. 21, 2024, which is hereby incorporated by reference herein in its entirety.

What is claimed is:

1. A measuring method comprising:
performing preliminary measurement for obtaining signal information obtained by detecting, using measurement light, a plurality of targets formed on a substrate a plurality of times while changing a parameter value of a measurement parameter;
acquiring a relationship between the parameter value and the signal information based on results of the preliminary measurement performed the plurality of times;
determining a target for which a main measurement should be performed, in the plurality of targets, based on the acquired relationship; and
performing the main measurement for the determined target.

2. The method according to claim 1, wherein the measurement parameter includes at least one of a central wavelength of the measurement light, a bandwidth of the wavelength, a σ value, or a polarization property in an optical path of a measuring apparatus for performing the preliminary measurement and the main measurement.

3. The method according to claim 2, wherein the signal information is at least one of a contrast, signal strength information, or position information of the plurality of targets.

4. The method according to claim 3, wherein the plurality of targets are patterns each formed by a plurality of line elements,
the measurement parameter is the central wavelength of the measurement light that illuminates the pattern,
the signal information is the contrast of each of the plurality of line elements,
in the acquiring, a relationship between the central wavelength and the contrast is acquired for each of the plurality of line elements, and
in the determining, of the plurality of line elements, a line element for which a maximum value of the contrast is less than a threshold in the relationship is excluded from a target of the main measurement.

5. The method according to claim 2, wherein the plurality of targets are patterns each formed by a plurality of line elements and are arranged in each of a plurality of predetermined shot regions set as sample region candidates on the substrate,
the measurement parameter is the central wavelength of the measurement light that illuminates the pattern,
the signal information is an asymmetry of a measurement signal,
in the acquiring, a relationship between the central wavelength and the asymmetry of the measurement signal is acquired for each of the plurality of predetermined shot regions, and
in the determining, of the plurality of predetermined shot regions, a shot region for which a minimum value of the asymmetry in the relationship exceeds a threshold is excluded from the sample region candidates.

6. The method according to claim 3, wherein the target is a pattern formed by a plurality of line elements, and
the determining includes obtaining a weight coefficient when indicating a position of the pattern by a weighted average of positions of the plurality of line elements.

7. The method according to claim 3, wherein the target is a pattern formed by a plurality of line elements, and
the determining includes setting a processing region for each of the plurality of line elements and determining a weight coefficient for each processing region based on an overlay measurement value for a plurality of shot regions on the substrate.

8. The method according to claim 4, wherein the pattern formed by the plurality of line elements is a line-and-space pattern having spaces between adjacent line elements.

9. The method according to claim 1, wherein the measurement parameter includes a position of the substrate in a rotation direction.

10. The method according to claim 9, wherein the performing the main measurement includes detecting at least one of a measurement error derived from a measuring apparatus that performs the preliminary measurement and the main measurement or a measurement error caused by a characteristic of a pattern formed on the substrate.

11. An article manufacturing method comprising:
measuring a position of a target on a substrate in accordance with the measuring method according to claim 1 and transferring a pattern to the substrate based on the position of the target; and
obtaining an article by processing the substrate with the pattern transferred.

12. A measuring apparatus comprising:
a measuring unit; and
a controller,
wherein the controller is configured to:
control the measuring unit such that preliminary measurement for obtaining signal information obtained by detecting, using measurement light, a plurality of targets formed on a substrate is performed a plurality of times while changing a parameter value of a measurement parameter,
acquire a relationship between the parameter value and the signal information based on results of the preliminary measurement performed the plurality of times,
determine a target for which a main measurement should be performed, in the plurality of targets, based on the acquired relationship, and
control the measuring unit to perform the main measurement for the determined target.

13. A lithography apparatus comprising:
the measuring apparatus according to claim 12, which is configured to measure a position of a mark provided on a substrate; and
a positioning mechanism configured to position the substrate based on the position of the mark measured using the measuring apparatus,
wherein the lithography apparatus is configured to transfer a pattern of the substrate.

14. An article manufacturing method comprising:
transferring a pattern to a substrate using the lithography apparatus according to claim 13; and
obtaining an article by processing the substrate with the pattern transferred.
